(19) United States
(12) Patent Application Publication
(10) Pub. No.: US 2025/0343507 A1
(43) Pub. Date: Nov. 6, 2025

(54) TEMPERATURE COMPENSATION FOR VOLTAGE-CONTROLLED OSCILLATORS

(71) Applicant: Micron Technology, Inc., Boise, ID (US)

(72) Inventors: Santosh Kattamuri, Bengaluru (IN); Parin Rajnikant Bhuta, Bangalore (IN)

(21) Appl. No.: 19/096,994

(22) Filed: Apr. 1, 2025

Related U.S. Application Data
(60) Provisional application No. 63/641,223, filed on May 1, 2024.

(51) Int. Cl. H03B 5/04; H03L 7/099

(52) U.S. Cl. CPC H03B 5/04; H03L 7/099; H03B 2200/004

(57) ABSTRACT

The present disclosure includes apparatuses and methods related to temperature compensation of voltage-controlled oscillators (VCOs). An example method includes performing a sweep of biasing voltage steps applied to an auxiliary varactor of a voltage-controlled oscillator (VCO) of a phase locked loop (PLL). For each of a plurality of the biasing voltage steps corresponding to the sweep: determining a frequency difference between a reference clock signal of the PLL and a VCO clock; and determining a difference between the determined frequency differences for the corresponding biasing voltage step and a different one of the plurality of biasing voltage steps. The method can include selecting a particular one of the plurality of biasing voltage steps as a target biasing voltage for the auxiliary varactor based on the calculated differences.

### PRIORITY INFORMATION

This application claims the benefit of U.S. Provisional Application No. 63/641,223, filed on May 1, 2024, the contents of which are incorporated herein by reference.

### TECHNICAL FIELD

The present disclosure relates generally to electronic apparatuses, and more particularly to apparatuses and methods associated with temperature compensation for voltage-controlled oscillators (VCOs) such as inductor-capacitor (LC) VCOs.

### BACKGROUND

Voltage-controlled oscillators (VCOs) find applications in various electronic systems where a variable and controllable oscillating signal is needed. For example, VCOs can be used in phase locked loops (PLLs) in association with providing an output signal whose phase is related to that of an input reference signal.

### BRIEF DESCRIPTION OF THE DRAWINGS

FIG. 1 is a block diagram of an electronic system having a temperature-compensated voltage-controlled oscillator (VCO) in accordance with a number of embodiments of the present disclosure.

FIG. 2 is a block diagram illustrating a more detailed example of a portion of the electronic system having a temperature-compensated VCO in accordance with a number of embodiments of the present disclosure.

FIG. 3 is a table associated with performing a sweep of bias voltages in association with performing temperature compensation for a VCO in accordance with a number of embodiments of the present disclosure.

FIG. 4 illustrates a method for VCO temperature compensation in accordance with a number of embodiments of the present disclosure.

FIG. 5 illustrates an example computer system within which a set of instructions can be executed in association with performing various embodiments of the present disclosure.

### DETAILED DESCRIPTION

The present disclosure includes apparatuses and methods related to temperature compensation for VCOs. VCOs, such as inductor-capacitor (LC) VCOs, are present in various electronic circuits (e.g., phase locked loops (PLLs)) within electronic systems and/or devices (e.g., memory devices, modulation/demodulation devices, synthesizers, etc.). The natural frequency of a VCO is affected by temperature, which can be due to the temperature dependence of metal oxide semiconductor (MOS) device parasitic junction capacitance. For example, the VCO frequency drops as temperature increases. A PLL, which can also include components such as a charge pump, loop filter, frequency divider, etc., can compensate for VCO temperature dependence. However, such compensation can require a large VCO gain (Kvco), which can increase the noise contribution of the various PLL components and lead to increased jitter and higher sensitivity to power supply induced noise, for example.

Current VCO temperature compensation solutions include open loop temperature compensation and closed loop temperature compensation. Open loop temperature compensation can involve an auxiliary varactor (also referred to as a secondary varactor) added in parallel to a main varactor (also referred to as the primary varactor), with the auxiliary varactor being independently controlled by a temperature-dependent voltage (Vbias). However, such open loop compensation schemes are inflexible in that the desired (e.g., optimal) Vbias varies across process corners, which can lead to over/under compensation of the frequency drift across a temperature range. Closed loop temperature compensation involves adding an auxiliary varactor in parallel with the main varactor, with the auxiliary varactor being controlled by the feedback from the PLL loop, which can lead to drawbacks such as additional sources of noise in the loop and stability concerns within the main PLL loop, for example.

Aspects of the present disclosure address the above and other deficiencies by providing a VCO temperature compensation scheme that delivers improved temperature compensation (e.g., reduced frequency drift) across various process corners. For example, embodiments can determine a target (e.g., optimum) bias point (e.g., temperature-compensated bias voltage) for an auxiliary varactor by performing a sweep of biasing voltage steps in order to determine the bias voltage that provides the minimum VCO frequency drift across a wide temperature range. Accordingly, embodiments can result in a smaller Kvco, which can reduce jitter performance as compared to prior approaches.

As used herein, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” The term “coupled” means directly or indirectly connected.

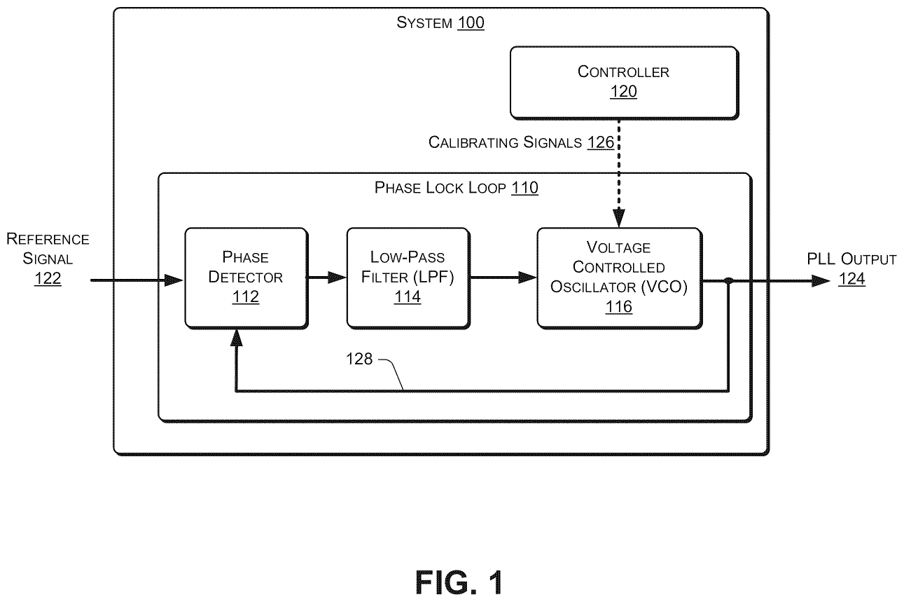

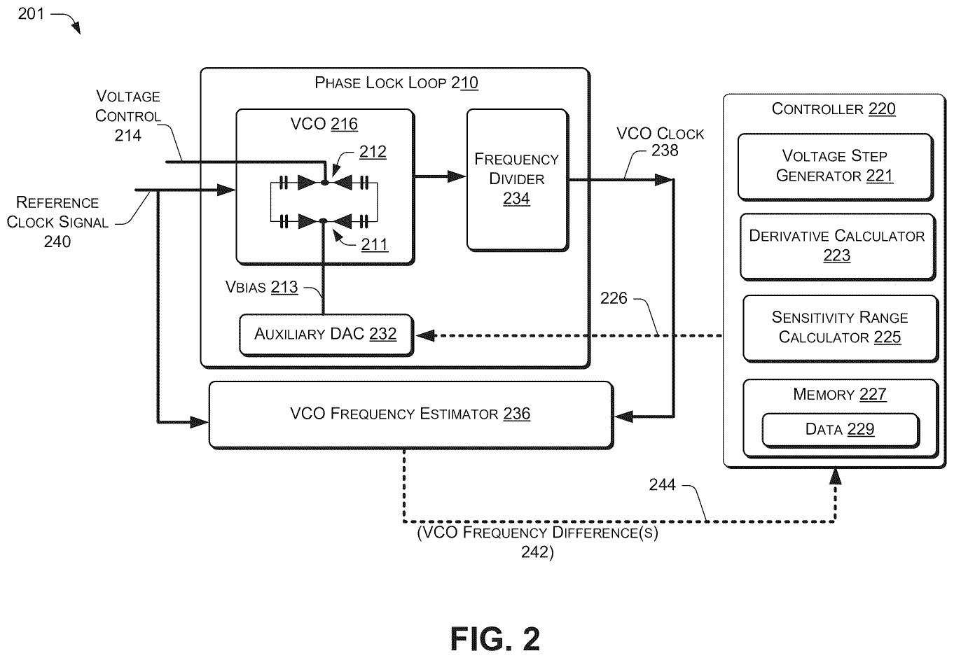

The figures herein follow a numbering convention in which the first digit or digits correspond to the drawing figure number and the remaining digits identify an element or component in the drawing. Similar elements or components between different figures may be identified by the use of similar digits. For example, 110 may reference element “10” in FIG. 1, and a similar element may be referenced as 210 in FIG. 2. Analogous elements within a Figure may be referenced with a hyphen and extra numeral or letter. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

FIG. 1 is a block diagram of an electronic system 100 having a temperature-compensated VCO 116 in accordance with a number of embodiments of the present disclosure. The system 100 can be, for example, a System-on-Chip (SoC); however, embodiments are not limited to a particular type of electronic system. In various embodiments, the VCO 116 can be implemented in a PLL 110 and may receive signals (e.g., control signals) via a controller 120, which can be a microcontroller comprising a sequencer and/or various other control circuitry.

In one embodiment, the system 100 may use the PLL 110 to implement frequency and phase tracking of a reference signal 122. For example, an output of the VCO 116 may include the same frequency and phase as that of the reference signal 122 to be detected. In this example, and to compensate for ambient temperature drifts that can affect the precision of tracking the frequency and/or phase of the reference signal 122, the controller 120 may be configured to determine an optimum Vbias, and to supply the determined optimum Vbias to the VCO 116. The optimum Vbias may include, for example, the operating voltage of an auxiliary varactor (not shown) in the VCO 116 that is determined to be within a maximum sensitivity range of the VCO 116. The maximum sensitivity range may be associated with a VCO region of operation where a small variation in the VCO control voltage can result in significant changes in the VCO frequency for the same Kvco.

As shown, the example system 100 may include the PLL 110 that is operably connected to the controller 120. The PLL 110 may include, without limitation, a phase detector 112, low-pass filter (LPF) 114 and the VCO 116 to generate a PLL output 124 that can include the detected frequency and/or phase of the input reference signal 122. The PLL 110 and particularly, the VCO 116, may receive calibrating signals 126 from the controller 120. For example, the calibrating signals 126 may include an initial sweeping set of biasing voltage steps to determine the optimum biasing voltage that can compensate for the ambient temperature drifts. The determined optimum biasing voltage (Vbias) may then be used as an input or controlling voltage to the auxiliary varactor, for example, of the temperature-compensated VCO 116. Additional components (not shown) may be associated with the system 100 to perform the calibration of the VCO 116.

The controller 120 may include a hardware, software, and/or firmware, or a combination thereof, that can be configured to calibrate the VCO 116. In one embodiment, the controller 120 may include components (not shown) to generate a sweep of biasing voltage steps with preconfigured increments, supply the generated biasing voltage steps to the VCO 116, and then perform or execute an algorithm to determine the target biasing voltage for the VCO 116. In this embodiment, the determined target biasing voltage may be used to operate the temperature-compensated VCO 116. In some embodiments, the controller 120 may perform this calibration over a predetermined period, or upon a detection of a triggering event. For example, the controller 120 may perform the calibration every minute, hour, etc. to determine the target biasing voltage of the temperature-compensated VCO 116. In another example, the controller 120 may perform the calibration upon detection of the start of operation of the system 100. In these examples, the controller 120 may use the calibrating signals 126 to supply the determined optimum or target biasing voltage to operate the VCO 116. As further described in FIG. 2, the controller 120 may use one or more components to generate the calibrating signals 126.

The PLL 110 may include circuitry that can be used for frequency and phase tracking, frequency synthesis, frequency modulation and/or demodulation, clock generation, frequency multiplication/division, and the like. For purposes of illustration, the shown PLL 110 in the system 100 is configured to implement the frequency and phase tracking of the input reference signal 112. Here, the controller 120 may calibrate the VCO 116 of the PLL 110 to maintain the accuracy of the frequency and phase tracking of the reference signal 112. This accuracy can be typically affected by the presence of unwanted signals or variations due to ambient temperature drifts.

For example, the PLL 110 may receive the reference signal 122 to be tracked by the system 100. The phase detector 112 may then compare the received reference signal 122 with a feedback signal 128 from an output of the VCO 116. The feedback signal 128 may include, for example, the output of the VCO 116 that is synchronized with the frequency and phase of the reference signal 122. In this example, the phase detector 112 may generate an error signal that is proportional to a frequency or phase difference between the reference signal 126 and the feedback signal 128.

Following the preceding example, the low-pass filter 114 may include circuitry that is configured to filter high-frequency components of the frequency or phase difference from the output of the phase detector 112. For example, the high-frequency components may include noise or unwanted signals that can be removed using the low-pass filter. In this example, the low-pass filter 114 may generate a filtered output signal that is used as a reference for adjusting the input voltage to the VCO 116. In some embodiments, the VCO 116 is controlled by a main varactor (not shown) and the auxiliary varactor (not shown) that is connected in parallel with the main varactor. Each of these varactors may have the same or different VCO gains (Kvco); however, the input or control voltage for the auxiliary varactor can be dynamically adjusted to compensate for temperature drifts. In some embodiments, the optimum bias point for the auxiliary varactor is fixed upon the calibration of the VCO 116.

In some embodiments, the control voltage that is supplied to the auxiliary varactor of the VCO 116 may not facilitate the generation of the desired PLL output 124 due to the ambient temperature drifts. In this case, the controller 120 may perform the calibration of the VCO 116 to compensate for the ambient temperature drifts as further described below.

FIG. 2 is a block diagram illustrating a more detailed example of a portion 201 of an electronic system having a temperature-compensated VCO 216 in accordance with a number of embodiments of the present disclosure. The portion 201 can be part of a system such as the system 100 described in FIG. 1.

The PLL 210, VCO 216, controller 220, and the calibrating signals 226 correspond to the PLL 110, VCO 116, controller 120, and the calibrating signals 126, respectively, of FIG. 1.

As shown in the portion 201 of the system, the PLL 210 may include the VCO 216 having an auxiliary varactor 211 and a main varactor 212. The auxiliary varactor 211 may receive a biasing voltage (Vbias) 213 from an auxiliary DAC 232 while the main varactor 212 can receive a separate voltage control 214 from the controller 220. The portion 201 further includes a frequency divider 234, and a VCO frequency estimator 236 that is coupled to an output of the PLL 210.

The output of the PLL 210 may include a VCO clock 238 that can be compared by the VCO frequency estimator 236 to a reference clock signal 240 to generate VCO frequency difference(s) 242. In an embodiment, the VCO frequency estimator 236 may supply the determined VCO frequency difference(s) 242 to the controller 220 via a feedback signal path 244. The VCO frequency difference(s) 242 may be used by the controller 220 to calculate the Vbias 213 that can be used as a control or operating voltage of the auxiliary varactor 211 to compensate for the ambient temperature drifts. For example, the Vbias 213 is associated with the VCO 116 maximum sensitivity range, which includes the VCO region of operation in which a small variation in the input voltage (Vbias 213) can result in significant changes in the VCO clock 238. In this example, significant changes in the VCO clock 238 may result without changing the VCO gain.

The controller 220 may include components such as, without limitation, a voltage step generator 221, derivative calculator 223, sensitivity range calculator 225, and memory 227 to generate the calibrating signals 226. The calibrating signals 226 may include the determined Vbias 213 to compensate for the ambient temperature drifts. The calibration signals 226 may include other instructions to configure or reconfigure other components within the PLL 210 during normal operation or in calibration mode.

For example, at the calibration mode, the PLL 210 may be reconfigured to receive the reference clock signal 240 from an external crystal oscillator (not shown), and to connect the VCO 216 to the auxiliary DAC 232 and the frequency divider 234. In this example, the reference clock signal 240 may include a preconfigured frequency and/or phase that can be used by the VCO 216 to calculate the VCO frequency difference(s) 242. The reference clock signal 240 is different from the reference signal 122 of FIG. 1 in the sense that the reference clock signal 240 includes a fixed frequency and/or phase while the reference signal 122 includes a varying frequency and/or phase that is tracked by the PLL 110.

In an embodiment, the auxiliary DAC 232 may convert a plurality of predetermined digital voltage steps into analog voltages (or analog biasing voltage steps). The digital voltage steps or signals may include discrete digital values or signals with predetermined increments that can be used as a sweeping set of biasing voltage steps to the VCO 216 during the calibration mode. In the illustrated embodiment where the auxiliary varactor 211 is used to control the VCO clock 238 of the VCO 216, the sweeping set of biasing voltage steps is supplied to the auxiliary varactor 211 of the VCO 216. The predetermined increments of these biasing voltage steps can be based on the number of voltage steps and range of the sweep to be applied during the calibration mode. In some embodiments, the auxiliary DAC 232 may be the same DAC that is used during regular operation of the PLL 210 to track the phase and frequency of the reference signal such as the reference signal 122 of FIG. 1. In an alternative embodiment, the auxiliary DAC 232 is independent of a main DAC (not shown) that is used during the regular operation of the PLL 210.

The main varactor 212 and the auxiliary varactor 211 may be used to generate variable capacitance in response to the voltages applied across their respective terminals. The main varactor 212 may be connected in parallel with the auxiliary varactor 211 to add their individual capacitances and thus increase the tuning range of the VCO 216, for example. In an embodiment, the voltage control 214 may facilitate the supplying of the operating voltage to the main varactor 212 while the determined Vbias 213 can be used to operate the auxiliary varactor 211 to implement the temperature-compensated VCO 216. In this embodiment, the main varactor 212 may supply the base capacitance while the auxiliary varactor 211 may add variable capacitance corresponding to the different voltage steps during calibration or the Vbias 213 during normal operation.

The frequency divider 234 may divide the output frequency of the VCO 216 with a particular division factor (not shown) to provide flexibility when the controller 220 (via VCO frequency estimator 236) performs a comparison between the VCO clock 238 and the reference clock signal 240 to determine the VCO frequency difference(s) 242. For example, in a case where the PLL 210 is operating at high frequencies, the frequency divider 234 may divide the output frequency by four to lower a reference output frequency that will be compared with the reference clock signal 240. In this example, the frequency divider 234 may use the same division factor across the sweeping set of voltage steps to generate the VCO clock 238.

The VCO frequency estimator 236 may include circuitry that is configured to compare, during the calibration mode, the VCO clock 238 with the reference clock signal 240 to generate a corresponding VCO frequency difference 242 for each of the supplied biasing voltage steps. The auxiliary varactor 211 receives the biasing voltage steps from the auxiliary DAC 232 at calibration mode. The generated corresponding VCO frequency difference 242 is communicated to the controller 220 via the feedback signal path 244. The communication may also include the configuration of the frequency divider 234 such as, for example, the division factor that is used to adjust the output frequency of the VCO 216.

The reference clock signal 240 may be generated by an oscillator (not shown) within or outside of the portion 201. During the calibration mode, the reference clock signal 240 may include a preconfigured signal that can be used as a reference by the VCO frequency estimator 236 to calculate the VCO frequency difference 242 for each of the (converted) sweeping set of biasing voltage steps that are supplied by the auxiliary DAC 232 to the VCO 216.

The voltage step generator 221 may include circuitry that can generate a plurality of digital control signals that induce a corresponding step change in the output frequency of the VCO 216. For example, each voltage step can induce a change in the output capacitance of the auxiliary varactor 211. The digital control signals can be in the form of a binary word or a digital code that is converted by the auxiliary DAC 232 into an analog biasing voltage step. In an embodiment, the step change in the voltage steps can be 0.25V, 0.3V, 0.5 mV, or various other step changes that can induce a corresponding step change in the output capacitance of the auxiliary varactor 211, which can generate a corresponding change to the VCO clock 238. The number of voltage steps can include a range of values that depend upon the amount of sweep to be applied to the VCO 216. In some cases, the number of voltage steps can include a range of values that depend upon a particular application of the PLL 210 and/or requirement of the electronic system 200.

The derivative calculator 223 can implement an algorithm that is used by the controller 220 to calculate the difference between the VCO frequency differences that are associated with different pairs of voltage steps. In an embodiment, the derivative calculator 223 may use a predetermined gap for identifying the pairs of voltage steps and their corresponding calculated differences. The predetermined gap can include the number of spaces or steps between the voltage steps in the pairs of voltage steps. The number of spaces or gaps can be one voltage step, two voltage steps, or more.

For example, the generated sweep set of biasing voltage steps can be ten, which includes a first voltage step, a second voltage step, and so on. In this example, in which the predetermined gap is two increments, the resulting pairings include the pairings between the first voltage step and the third voltage step; the second voltage step and the fourth voltage step; the third voltage step and the first voltage step; the fourth voltage step and the sixth voltage step; the fifth voltage step and the seventh voltage step; the sixth voltage step and the eight voltage step; the seventh voltage step and the ninth voltage step; and the eighth voltage step and the tenth voltage step. The number of pairings from this sweep is eight because the ninth voltage step and the tenth voltage step have already been paired with the seventh voltage and eight voltage steps, respectively.

The sensitivity range calculator 225 may include circuitry that is configured to identify the VCO frequency differences 242 and associated voltage steps that are within a targeted sensitivity range. For example, the sensitivity range calculator 225 may use a basic comparison algorithm to rank the calculated values of the differences between the VCO frequency differences 242 from the different pairs of voltage steps. In this example, the identified top-ranking differences may be associated with the maximum sensitivity range of the VCO. The maximum sensitivity range of the VCO may be associated with the VCO's region of operation where small variations in the input biasing voltage step to the auxiliary varactor 211 may result in substantially high changes in the VCO clock 238.

As described herein, the maximum or targeted sensitivity range of the VCO 216 may depend upon a specific application of the VCO 216 and requirements of the electronic system 200 in which the VCO 216 is used. In one example in which the VCO 216 is used for frequency and phase tracking, the targeted sensitivity range may include above-threshold amounts of differences in the VCO frequency differences 242 from the different pairs of voltage steps. The above-threshold amounts of changes may be associated with maximum sensitivity points where a small change in the input analog signal can induce a substantial change in the output frequency of the VCO. In some cases, the controller 220 may use a predetermined targeted sensitivity range of the VCO 216 from its manufacturer specification to identify one or more analog voltages that are associated with the targeted sensitivity range of the VCO 216.

The memory 227 may store data 229 that can be used to support the calibration of the VCO 216. Without limitation, the data 229 can include current and previous configurations of the VCO 216, supplied calibration signals 226, history of biasing voltages that were calculated to compensate for the ambient temperature drifts, and/or output of the one or more components in the controller 220.

In an embodiment, the memory 227 may include non-transitory computer-readable media, such as volatile and nonvolatile, removable, and non-removable media implemented in any suitable method or technology for storage of information, such as computer-readable instructions, data structures, program modules, or other data. System memory, removable storage, and non-removable storage are all examples of non-transitory computer-readable media. Examples of non-transitory computer-readable media include but are not limited to, RAM, ROM, EEPROM, flash memory or other memory technology, CD-ROM, digital versatile disks (DVD) or other optical storage, magnetic cassettes, magnetic tape, magnetic disk storage, or other magnetic storage devices, or any suitable non-transitory medium which can be used to store the desired information.

In an example operation, the controller 220 may initiate the calibration process for the VCO 216 by reconfiguring the connection of the VCO 216 to connect to the auxiliary DAC 232, frequency divider 234, reference clock signal 240, and the VCO frequency estimator 236. For example, the auxiliary DAC 232 is coupled to the VCO 216 to supply the analog voltages to the auxiliary varactor 211 while the frequency divider 234 can be connected to divide the output of the VCO 216. In this example, the output (VCO clock 238) of the frequency divider 234 and the reference clock signal 240 are configured to couple to the VCO frequency estimator 236. In some cases where the frequency divider 234 is not needed (e.g., VCO 216 is not operating at high frequencies), the output (VCO clock 238) of the VCO 216 can be directly coupled to the VCO 216.

At the calibration mode, the controller 220 may use the voltage step generator 221 to generate a plurality of voltage steps that can be used as sweeping set of biasing voltages for the VCO 216. For example, the plurality of voltage steps may include digital control signals that induce a corresponding step change in the output capacitance (and thus, frequency) of the auxiliary varactor 211 of the VCO 216. In this example, the total capacitances of the main varactor 212 and the auxiliary varactor 211 are added to generate a corresponding output of the VCO 216. In this example still, the corresponding step change is separated by preconfigured increments between each of the digital control signals. Each of the digital control signals is converted into corresponding analog signals using the auxiliary DAC 232.

In an embodiment, the controller 220 may use the VCO frequency estimator 236 to generate the corresponding VCO frequency differences 242 for each of the converted biasing voltage steps that is supplied by the auxiliary DAC 232 to the auxiliary varactor 211. For example, the plurality of voltage steps includes ten voltage steps with a fixed increment. In this example, the VCO frequency estimator may calculate ten VCO frequency differences corresponding to these ten voltage steps.

The VCO frequency estimator 236 may send the calculated VCO frequency differences 242 to the controller 220 via the feedback signal path 244. In an embodiment, the memory 227 may store the calculated VCO frequency differences 242 including the corresponding digital control signals that were used to generate the VCO frequency differences 242. For example, ten VCO frequency differences 242 can be calculated from the ten biasing voltage steps that will be supplied to the VCO 216. In this example, the memory 227 may store the ten VCO frequency differences and the corresponding biasing voltage steps.

In one embodiment, the controller 220 may use the predetermined gap between voltage steps to identify the different pairs of voltage steps. For example, the predetermined gap may include a fixed number of increments in between a first voltage step and a second voltage step that form the pair of voltage steps. In this example, the number of increments can include one increment-gap, two increments-gap, three increments-gap, and so on, from the first voltage step.

With the identified pairs of voltage steps, the controller 220 may use the derivative calculator 223 to determine the differences between the VCO frequency differences 242 that are associated with the different pairs of voltage steps. For example, the plurality of digital control signals or voltage steps is five, which includes a first voltage step, a second voltage step, and so on. In this example, where the predetermined gap is two increments or voltage steps away from a reference voltage step, then the resulting number of pairs may include the pairings between the first voltage step and the third voltage step; the second voltage step and the fourth voltage step; and the third voltage step and the fifth voltage step. In some embodiments, the derivative calculator 223 may implement an algorithm (e.g., subtraction algorithm) to determine the differences or changes in the VCO frequency differences 242 between the first voltage step and the third voltage step; the second voltage step and the fourth voltage step; and the third voltage step and the fifth voltage step.

In an embodiment, the sensitivity range calculator 225 may use a ranking algorithm to identify the calculated differences that are associated with the maximum or targeted sensitivity range (not shown) of the VCO 216. In the example above, the first pair may include the first voltage step and the third voltage step; the second pair includes the second voltage step and the fourth voltage step; and the third pair includes the third voltage step and the fifth voltage step. In this example, the sensitivity range calculator 225 may use the ranking algorithm to identify the one or more top-ranked pairs that can be associated with the maximum sensitivity range of the VCO 216. In some embodiments, the maximum sensitivity range may depend upon a specific application of the VCO 216 and requirements of the electronic system 200 in which the VCO 216 is used. In one example where the VCO 216 is used for frequency and phase tracking, the maximum sensitivity range may include substantial changes in the VCO clock 238 in response to a change in the supplied analog voltages.

Upon identification of one or more voltage steps that are associated with the maximum sensitivity range of the VCO 216, the controller 220 may use a threshold value to identify the voltage step that can be used as the optimum biasing voltage for the VCO 216. The optimum biasing voltage includes the voltage that compensates for the detected thermal condition that may affect the operation of the VCO 216. In one example, the threshold value for the selection of the biasing voltage can include a user-selected threshold value that is stored in the memory 227. In another example, the threshold value can be taken from the manufacturer specification of the VCO 216.

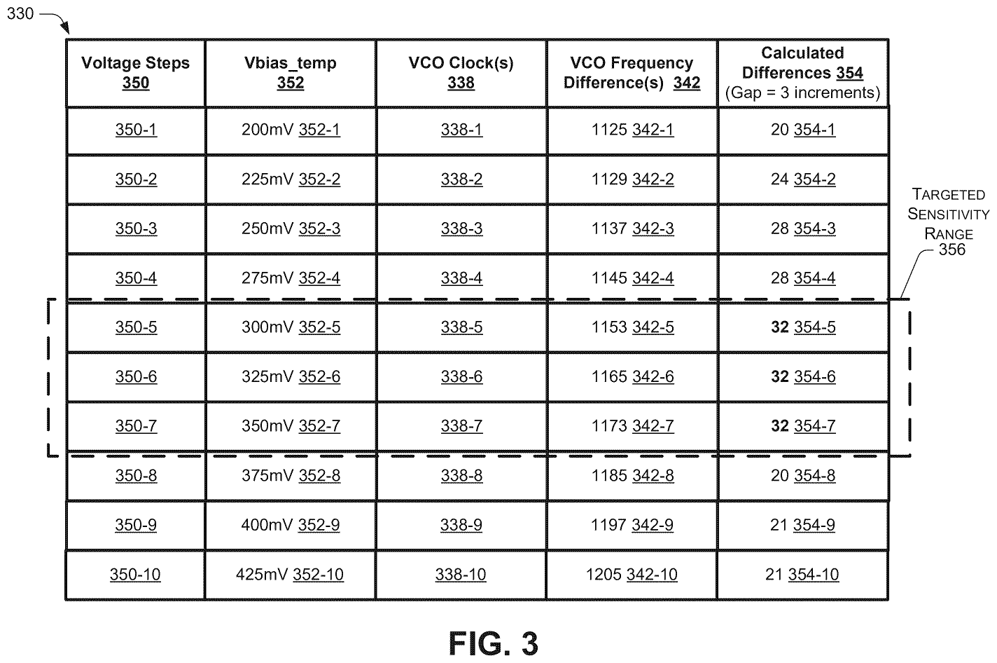

FIG. 3 is a table 330 associated with performing a sweep of biasing voltage steps in association with performing temperature compensation for a VCO in accordance with a number of embodiments of the present disclosure.

As shown, columns of the table 330 may include voltage steps 350, sweeping voltages (Vias_temp) 352, VCO clock(s) 338, VCO frequency difference(s) 342, and calculated differences 354. During the calibration mode, the controller (120, 220) can use at least the calculated differences 354 in table 330 to select the biasing voltage (Vbias) that can be used to operate the auxiliary tor 211 of the temperature-compensated VCO 216. For illustration purposes, only ten voltage steps 350-1 to 350-10 are shown although multiple other voltage steps with fixed increments may be added as sweeping voltages during the calibration mode.

The voltage steps 350-1 to 350-10 have corresponding sweeping voltages (Vbias_temp) 352-1 to 352-10 that include different analog voltage signals with a predetermined increment. The voltage steps 350-1 to 350-10 can correspond to respective DAC codes (e.g., codes of DAC 232). The predetermined increment can be 0.1V, 0.25V, 25 mV, or any other discrete increment that induces a step change in the VCO clock 338. In the illustrated table 330, the increment is 25 mV between voltage steps. For example, the step change in voltage between the voltage steps 350-1 and 350-2 is 25 mV, the step change in voltage between the voltage steps 350-2 and 350-3 is 25 mV, and so on.

The sweeping voltages (Vias_temp) 352-1 to 352-10 may include the converted sweep set of biasing voltage steps. For example, each of the generated plurality of voltage steps is converted into analog signal by the auxiliary DAC 232. In this example, the sweeping voltages (Vias_temp) 352-1 to 352-10 are representative of this converted sweep set of biasing voltage steps.

The VCO clocks 338-1 to 338-10 may include the corresponding output of the VCO (116, 216) for each of the sweeping voltages (Vias_temp) 352-1 to 352-10. For example, the VCO clock 338-1 is the output of the VCO (116, 216) when the 200 mV 352-1 is used as the input voltage to the auxiliary varactor 211, the VCO clock 338-2 is the output of the VCO (116,216) when the 225 mV 352-2 is used as the input voltage to the auxiliary varactor 211, and so on.

The VCO frequency differences 342-1 to 342-10 may represent the corresponding calculated differences between each of the VCO clocks 338-1 to 338-10 and the reference clock signal (e.g., reference clock signal 240). For example, the difference between the VCO clock 338-1 and the reference clock signal 240 may produce the VCO frequency difference 322-1, the difference between the VCO clock 338-2 and the reference clock signal 240 may produce the VCO frequency difference 322-2, and so on. The values “1125,” “1129,” “1137” and so on, which are associated with the column 342 are example estimates of the calculated VCO frequency differences between each of the VCO clocks 338 and the reference clock signal 240.

The calculated difference(s) 354 may include the calculated differences between the VCO frequency differences associated with the identified pairs of voltage steps. In one embodiment, the derivative calculator 223 in FIG. 2 may be configured to calculate the corresponding values of the calculated differences 354. In this embodiment, the derivative calculator 223 may utilize the predetermined gap to identify the pairs of voltage steps before performing the calculations.

For instance, in the example shown in FIG. 3, a predetermined gap of three voltage steps is used to identify the pairs of voltage steps. In this example, the pairing of voltage steps includes the first pairing between the voltage steps 350-1 and 350-4; second pairing between the voltage steps 350-2 and 350-5; third pairing between the voltage steps 350-3 and 350-6; fourth pairing between the voltage steps 350-4 and 350-7, fifth pairing between the voltage steps 350-5 and 350-8; sixth pairing between the voltage steps 350-6 and 350-9; and seventh pairing between the voltage steps 350-7 and 350-10. In an embodiment, the derivative calculator 223 may calculate each of the calculated differences 354 by determining the difference between the VCO frequency differences in each of these identified voltage pairs. For example, the value “20” in the calculated difference 354-1 is the difference between the “1145” and “1125” of the VCO frequency difference 342-1 and VCO frequency difference 342-4, respectively. In another example, the value “24” in the calculated difference 354-2 is the difference between the “1153” and “1129” of the VCO frequency difference 342-2 and VCO frequency difference 342-5, respectively, and so on.

In an embodiment, a targeted sensitivity range 356 (also called maximum sensitivity range) may include the voltage steps 350 that are associated with top-ranked calculated differences between the VCO frequency differences. The values of the calculated differences 354 may indicate the degree of sensitivity among the different voltage steps 350. For example, the calculated differences 354 that are associated with the higher number of calculated differences may indicate a higher amount of sensitivity and thus, facilitate the VCO to operate in a region where small changes in the sweeping voltages (Vias_temp) 352 can result in high variations in the VCO clocks 338.

In an embodiment, the targeted sensitivity range 356 may be identified by a comparison between the calculated values of the calculated differences 354. For example, the controller may use the basic comparison algorithm to rank the values of the calculated differences 354. In this example, the controller may identify the calculated differences 354 that are associated with high-ranking values. As shown, the calculated differences 354-5 to 354-7 having calculated differences of 32, 32, and 32, respectively, may be treated as being associated with the targeted sensitivity range 356 because they have the top-ranked calculated differences as compared to the rest of the calculated differences.

In another example, the controller may use a threshold value to identify the minimum amount of calculated difference 354 that will be included in the targeted sensitivity range 356. For example, the threshold value is 30. In this case, the voltage steps 350 that are associated with the calculated differences 354 that are above the threshold value of 30 are assumed to include the maximum sensitivity for a step change in the sweeping voltage.

Upon identification of the one or more voltage steps 350 that are associated with the targeted sensitivity range 356, the controller may select one of the one or more voltage steps 350 as biasing voltage that can be used to bias the auxiliary varactor 211 of the VCO 216 during normal operation. For example, referencing the determined targeted sensitivity range 356, the controller may select the voltage step 350-6 that is associated with the 325 mV 352-6 as the biasing voltage for the VCO during normal operation. In some embodiments, the controller may use another threshold value from the manufacturer specification for selecting the biasing voltage.

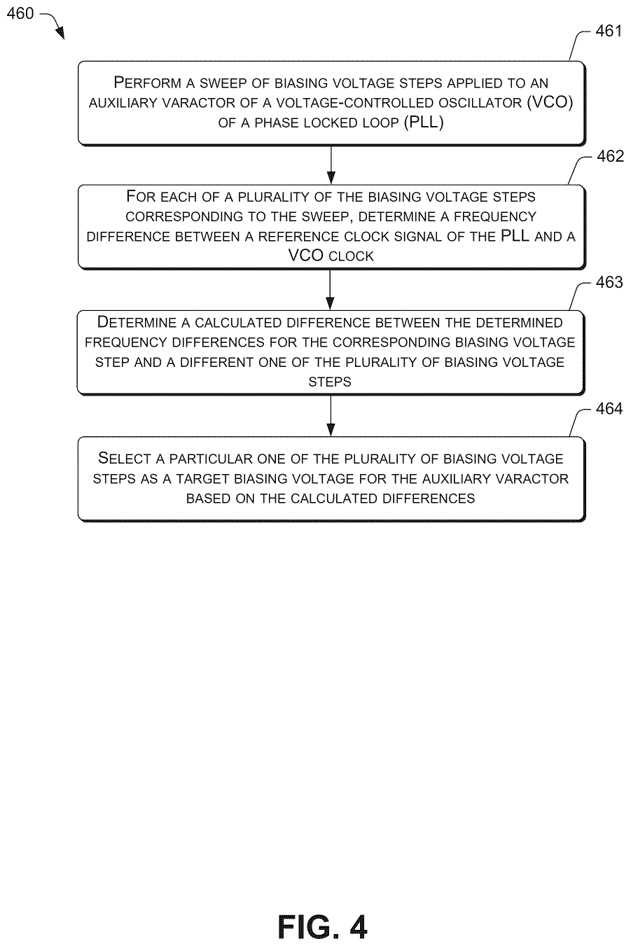

FIG. 4 illustrates a method 460 for VCO temperature compensation in accordance with a number of embodiments of the present disclosure.

The method can be performed by processing logic that can include hardware (e.g., a processing device, circuitry, dedicated logic, programmable logic, microcode, hardware of a device, integrated circuit, etc.), software (e.g., instructions run or executed on a processing device), or a combination thereof. One or more processes can be omitted in various embodiments. Thus, not all processes are required in every embodiment. Other process flows are possible.

At block 461, the controller may perform a sweep of biasing voltage steps applied to an auxiliary varactor of a VCO of a PLL. For example, the controller may be configured to generate a plurality of biasing voltage steps during a calibration mode. Referring to FIG. 3, the voltage steps 350 may correspond to the sweeping voltages (Vias_temp) 352 that include different analog voltage signals with a predetermined increment.

In some embodiments, the controller may convert each of the plurality of voltage steps into corresponding analog signals. For example, referring to FIG. 2, the auxiliary DAC 232 may convert a sweeping set of biasing voltage steps into analog voltages. The sweeping set of biasing voltage steps may include discrete digital values or signals with predetermined increments that can be used as sweeping voltages for the auxiliary varactor 211 of the VCO 216 during the calibration mode.

After the conversion, the controller may supply the analog signals to the auxiliary varactor of the VCO to generate corresponding VCO clocks. For example, the analog signals are supplied to the auxiliary varactor 211 of the VCO 216 in FIG. 2 after the conversion of the digital voltage steps by the auxiliary DAC 232. For each analog signal, a corresponding VCO clock may be generated by the VCO.

At block 462, for each of a plurality of the biasing voltage steps corresponding to the sweep, the controller may determine a frequency difference between a reference clock signal of the PLL and a VCO clock. In some embodiments, the controller may calculate VCO frequency differences based at least upon a comparison between the VCO clocks and a reference clock signal. For example, referring to FIG. 2, the VCO frequency estimator 236 may use an algorithm to compare the VCO clock 238 with the reference clock signal 240 to generate a corresponding VCO frequency difference 242. In this example, the VCO frequency estimator 236 may generate a VCO frequency difference 242 for each of the sweeping voltages that are supplied by the auxiliary DAC 232 to the auxiliary varactor 211.

At block 463, the controller may determine a calculated difference between the determined frequency differences for the corresponding biasing voltage step and a different one of the plurality of biasing voltage steps. In some embodiments, the controller may calculate differences between the VCO frequency differences associated with different pairs of voltage steps. For example, referring to FIG. 2, the derivative calculator 223 can implement an algorithm to determine the differences between the VCO frequency differences that are associated with the different pairs of voltage steps. In an embodiment, the derivative calculator 223 may use a predetermined gap for identifying the pairs of voltage steps.

At block 464, the controller may select a particular one of the plurality of biasing voltage steps as a target biasing voltage for the auxiliary varactor based on the calculated differences. In some embodiments, the controller may identify one or more voltage steps that are associated with a targeted sensitivity range of the VCO. For example, in reference to FIG. 2, the controller 220 may use the basic comparison algorithm to rank the values of the calculated differences. In this example, the controller 220 may identify the calculated differences that are associated with high-ranking values. In another example, the controller may use a threshold value to identify the minimum value of the calculated difference(s) that will be included in the targeted sensitivity range. In this example, the voltage steps that are associated with the targeted sensitivity range are assumed to include maximum sensitivity for a step change in the sweeping voltage.

In some embodiments, the controller may select one of the identified one or more voltage steps as a biasing voltage for the VCO.

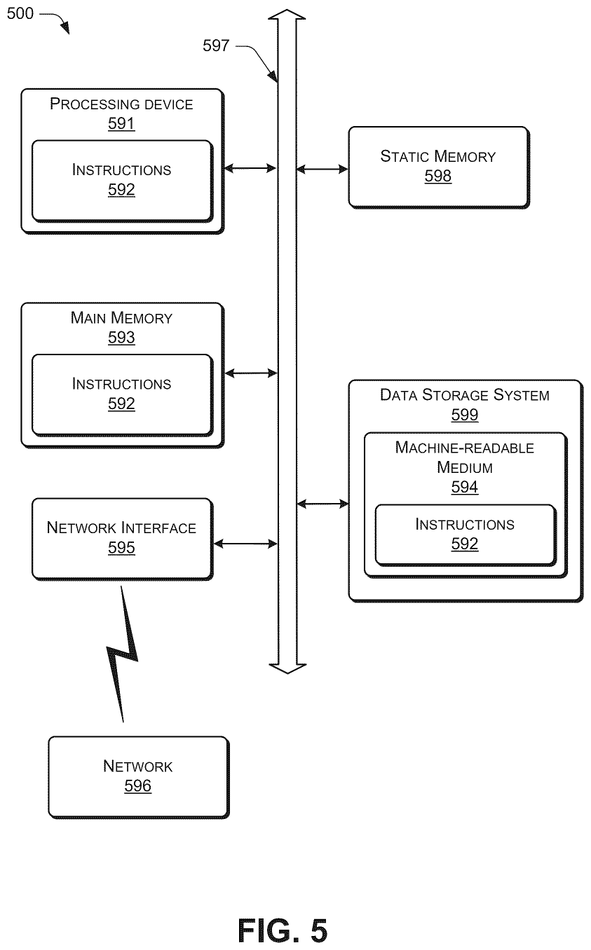

FIG. 5 illustrates an example computer system 500 within which a set of instructions can be executed in association with performing various embodiments of the present disclosure. In various embodiments, the computer system 500 can correspond to a system (e.g., the electronic system 100 described with respect to Figure) that includes, is coupled to, or utilizes a memory sub-system or can be used to perform the operations of control circuitry (e.g., controller 120). In alternative embodiments, the system can be connected (e.g., networked) to other systems and/or devices in a LAN, an intranet, an extranet, and/or the Internet. The system can operate in the capacity of a server or a client machine in client-server network environment, as a peer device in a peer-to-peer (or distributed) network environment, or as a server or a client machine in a cloud computing infrastructure or environment.

The system 500 can be a personal computer (PC), a tablet PC, a set-top box (STB), a Personal Digital Assistant (PDA), a cellular telephone, a web appliance, a server, a network router, a switch or bridge, or any device capable of executing a set of instructions (sequential or otherwise) that specify actions to be taken by that device. Further, while a single system is illustrated, the term “system” shall also be taken to include any collection of systems that individually or jointly execute a set (or multiple sets) of instructions to perform any one or more of the methodologies discussed herein.

The example computer system 500 includes a processing device 591, a main memory 593 (e.g., read-only memory (ROM), flash memory, dynamic random access memory (DRAM) such as synchronous DRAM (SDRAM) or Rambus DRAM (RDRAM), etc.), a static memory 598 (e.g., flash memory, static random access memory (SRAM), etc.), and a data storage system 599, which communicate with each other via a bus 597.

The processing device 591 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 591 can also be one or more special-purpose processing devices such as an application specific integrated circuit (ASIC), a field programmable gate array (FPGA), a digital signal processor (DSP), network processor, or the like. The processing device 591 is configured to execute instructions 592 for performing the operations and steps discussed herein. The computer system 500 can further include a network interface device 595 to communicate over the network 596.

The data storage system 599 can include a machine-readable storage medium 594 (also known as a computer-readable medium) on which is stored one or more sets of instructions 592 or software embodying any one or more of the methodologies or functions described herein. The instructions 592 can also reside, completely or at least partially, within the main memory 593 and/or within the processing device 591 during execution thereof by the computer system 500, the main memory 593 and the processing device 591 also constituting machine-readable storage media.

The instructions 592 can be executed to carry out various embodiments described herein. For example, the instructions 592 can be executed to implement functionality corresponding to the electronic system 100, and/or the controller 120 or 220 of FIGS. 1-2. Such functionality can be temperature compensation for VCOs, for example.

While the machine-readable storage medium 594 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the system 500 and that cause the system 500 to perform any one or more of the methodologies of the present disclosure. The term “machine-readable storage medium” shall accordingly be taken to include, but not be limited to, solid-state memories, optical media, and magnetic media.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
performing a sweep of biasing voltage steps applied to an auxiliary varactor of a voltage-controlled oscillator (VCO) of a phase locked loop (PLL);
for each of a plurality of the biasing voltage steps corresponding to the sweep:
determining a frequency difference between a reference clock signal of the PLL and a VCO clock; and
determining a difference between the determined frequency differences for the corresponding biasing voltage step and a different one of the plurality of biasing voltage steps; and
selecting one of the plurality of biasing voltage steps as a target biasing voltage for the auxiliary varactor based on the calculated differences.

2. The method of claim 1 further comprising:
generating the plurality of biasing voltage steps;
converting the plurality of biasing voltage steps into corresponding analog signals; and
supplying the corresponding analog signals to the auxiliary varactor.

3. The method of claim 1, wherein the plurality of biasing voltage steps is separated by a voltage increment that induces a corresponding step change to the VCO clock.

4. The method of claim 1 further comprising:
setting a predetermined gap; and
using the predetermined gap to identify pairs of biasing voltage steps,
wherein the determined difference is based on a comparison between the VCO frequency differences associated with each of the identified pairs of biasing voltage steps.

5. The method of claim 4, wherein the predetermined gap includes a gap of at least one increment between the biasing voltage steps.

6. The method of claim 1, further comprising performing a calibration of the VCO via calibrating signals provided by a controller.

7. The method of claim 1 further comprising:
using a comparison algorithm to rank the determined calculated differences; and
identifying top-ranked calculated differences to be associated with a targeted sensitivity range of the VCO.

8. The method of claim 1, wherein the performing of the sweep of biasing voltage steps is implemented at a predetermined time period.

9. The method of claim 1, wherein the VCO is a part of the PLL that implements frequency and phase tracking of a reference signal.

10. A system, comprising:
a phase locked loop (PLL) including a voltage-controlled oscillator (VCO);
a digital-to-analog converter (DAC) coupled to an auxiliary varactor of the VCO; and
a controller coupled to the VCO and the DAC, the controller configured to:
perform a sweep of biasing voltage steps applied to the auxiliary varactor;
for each of a plurality of the biasing voltage steps corresponding to the sweep:
determine a frequency difference between a reference clock signal of the PLL and a VCO clock; and
determine a calculated difference between the determined frequency differences for the corresponding biasing voltage step and a different one of the plurality of biasing voltage steps; and
select a particular one of the plurality of biasing voltage steps as a target biasing voltage for the auxiliary varactor based on the calculated differences.

11. The system of claim 10, wherein the controller is further configured to:
generate the plurality of biasing voltage steps; and
use the DAC to convert the plurality of biasing voltage steps into corresponding analog signals,
wherein the corresponding analog signals are supplied to the auxiliary varactor to generate a corresponding VCO clock.

12. The system of claim 10, wherein the controller is further configured to:
set a predetermined gap; and
use the predetermined gap to identify pairs of biasing voltage steps,
wherein the determined calculated difference is based on a comparison between the VCO frequency differences associated with each of the identified pairs of biasing voltage steps.

13. The system of claim 10, wherein the plurality of biasing voltage steps is separated by a voltage increment that induces a corresponding step change in the VCO clock.

14. The method of claim 10, wherein the controller is further configured to:
use a comparison algorithm to rank the determined calculated differences; and
identify top-ranked calculated differences to be associated with a targeted sensitivity range of the VCO.

15. The system of claim 10, wherein the controller is configured to perform the sweep of biasing voltage steps at a predetermined time period.

16. The system of claim 10, wherein the VCO further comprises a main varactor that is connected in parallel to the auxiliary varactor to generate the VCO clock.

17. An apparatus, comprising:
a voltage-controlled oscillator (VCO) comprising a main varactor that is connected in parallel to an auxiliary varactor;
a digital-to-analog converter (DAC) coupled to the auxiliary varactor of the VCO; and
a controller coupled to the VCO and the DAC, the controller configured to:
generate a plurality of biasing voltage steps;
for each of the plurality of the biasing voltage steps:
generate a corresponding VCO clock;
determine a frequency difference between the corresponding VCO clock and a reference clock signal; and
determine a difference between the determined frequency differences for the corresponding biasing voltage step and a different one of the plurality of biasing voltage steps; and
select a particular one of the plurality of biasing voltage steps as a target biasing voltage for the auxiliary varactor based on the calculated differences.

18. The apparatus of claim 17, wherein the controller is further configured to:
use a comparison algorithm to rank the determined calculated differences; and
identify top-ranked calculated differences to be associated with a targeted sensitivity range of the VCO.

19. The apparatus of claim 17, wherein the controller is further configured to:
set a predetermined gap; and
use the predetermined gap to identify pairs of biasing voltage steps;
compare the VCO frequency differences associated with each of the identified pairs of biasing voltage steps to determine the difference.

20. The apparatus of claim 17, wherein the plurality of biasing voltage steps are separated by a voltage increment that induces a corresponding step change in the VCO clock.
